(19) United States
(12) Patent Application Publication
(10) Pub. No.: US 2022/0149555 A1
(43) Pub. Date: May 12, 2022

(54) CONTACTOR BLOCK OF SELF-ALIGNING VERTICAL PROBE CARD AND MANUFACTURING METHOD THEREFOR

(71) Applicant: MICRO FRIEND CO., LTD, Seoul (KR)

(72) Inventors: Yong Ho CHO, Yongin-si Gyeonggi-do (KR); Jong Myeon LEE, Gwacheon-si, Gyeonggi-do (KR)

(21) Appl. No.: 17/419,395

(22) PCT Filed: Dec. 30, 2019
(86) PCT No.: PCT/KR2019/018689

§ 371 Date: Jun. 29, 2021

(30) Foreign Application Priority Data
Dec. 31, 2018 (KR) 10-2018-0174001
Dec. 12, 2019 (KR) 10-2019-0165195
Dec. 30, 2019 (KR) 10-2019-0177633

(51) Int. Cl. H01R 13/405; H01R 13/22; H01R 43/24; H01R 43/16; G01R 1/067; G01R 1/073; G01R 3/00; G01R 31/28

(52) U.S. Cl. CPC H01R 13/405; H01R 13/22; H01R 43/24; G01R 31/2886; G01R 1/06744; G01R 1/07307; G01R 3/00; H01R 43/16

(57) ABSTRACT

A contactor block of a self-aligning vertical probe card according to the present invention comprises: at least one vertical contactor array in which a plurality of vertical contactors manufactured by a MEMS process and extending in the longitudinal direction are arranged side by side in the horizontal direction; and a molding layer that exposes the upper and lower ends of the plurality of vertical contactors constituting the vertical contactor array and surrounds and supports the plurality of vertical contactors.

### TECHNICAL FIELD

The present invention relates to a contactor block of a self-aligning vertical probe card allowing work efficiency for assembling a contactor block to a probe head module of a probe card to be improved and manufacturing costs to be reduced and a method of manufacturing the contactor block.

### BACKGROUND ART

A semiconductor manufacturing process is performed through a fabrication process of forming patterns on a wafer, an electrical die sorting (EDS) process of testing electrical characteristics of chips included in the wafer, and an assembly process of assembling individual chips separated from the wafer on which the patterns are formed.

The EDS process is for determining defective chips among the chips included in the wafer, and a test device called a probe card which applies an electrical signal to each chip and determines defects through a signal checked from the applied electrical signal is mainly used in the EDS process.

The probe card includes a plurality of contactors which apply the electrical signals to a pattern of the chip included in the wafer, and generally, the contactors of the probe card are brought into contact with electrode pads of a device of the wafer, a predetermined current is applied through the contactors, and output electric characteristics are measured.

Generally, the probe card includes a probe head module supporting vertical contactors. As illustrated in FIG. 1, a jig plate 3 for forming a gap between an upper guide plate 1 and a lower guide plate 2 is installed in the probe head module, both ends of a plurality of vertical probes 4 are inserted into insertion holes of the upper guide plate 1 and insertion holes of the lower guide plate 2. For example, in U.S. Pat. No. 6,515,496, a testing head having microstructures is disclosed. In this patent, a contact probe is installed between an upper guide plate and a lower guide plate. Particularly, one side of the contact probe is inserted into a guide hole formed in the upper guide plate, and the other side of the contact probe is inserted into a guide hole formed in the lower guide plate.

As another related art, a vertical probe card is disclosed in Korean Patent Registration No. 10-1869044. As illustrated in FIG. 2, in this patent document, a jig plate J for maintaining a gap is interposed between a first guide plate 10 installed close to a space transformer K and a second guide plate 20 installed close to a test target object, and both ends of needle units 30 are installed to be inserted into each of a plurality of insertion holes 21 formed in first guide plate and a plurality of insertion holes 21 formed in the second guide plate.

Meanwhile, since recent semiconductor devices have been highly integrated and extremely miniaturized while design rules has been further reduced, in order to come into contact with a pattern of the miniaturized semiconductor device, contactors of a probe card need to be miniaturized to have suitable sizes and narrow pitches disposed at narrow intervals that are smaller than a gap between connectors are needed.
[Patent Document 1]

U.S. Pat. No. 6,515,496 (Microstructure testing head)
[Patent Document 2]

Korean Patent Registration No. 10-1869044 (Needle unit for vertical probe card with reduced scrub phenomenon and vertical probe using thereof)

### Technical Problem

In vertical probe cards according to the related art including technology disclosed in the patent documents, vertical contactors are inserted into insertion holes of guide plates, and a probe card is assembled using the guide plates. In the related art, since many insertion holes should be machined in the plurality of guide plates as the number of the vertical contactors is increased, manufacturing time is greatly increased, since vertical probes should be inserted one by one into the insertion holes formed in the plurality of guide plates spaced apart from each other at predetermined intervals when the vertical contactors are assembled to the probe card, the time and manpower required for assembly work increases, and since the insertion holes of the plurality of guide plates do not exactly match to correspond to each other, the insertion holes repeatedly come into contact with the vertical contactors, thereby damaging the vertical contactors, and thus there is a problem in that test failures occur.

The present invention is directed to providing a contactor block of a self-aligning vertical probe card allowing work efficiency for assembling the contactor block to a probe head module to be improved and manufacturing costs to be reduced, and a method of manufacturing the contactor block of a self-aligning vertical probe card.

### Technical Solution

One aspect of the present invention provides a contactor block of a self-aligning vertical probe card, including one or more vertical contactor arrays which are manufactured through a micro-electro mechanical system (MEMS) process and in which a plurality of vertical contactors extending in a longitudinal direction are arranged parallel to a horizontal direction, and a molding layer which exposes upper ends and lower ends of a plurality of vertical contactors included in the vertical contactor array and surrounds and supports the plurality of vertical contactors.

The contactor block may further include base guide plates in which the vertical contactor array and the molding layer are integrally formed, wherein the plurality of base guide plates may be stacked in layers on a mounting base to form a contactor block, and the contactor block may be separated from the base guide plates using a laser cutting process.

A plurality of support rods having a predetermined height may be formed to protrude from a flat plate shaped body of the mounting base, and a plurality of insertion holes passing through the base guide plate may be fitted onto the support rods of the mounting base so that the plurality of vertical contactor arrays may be arranged.

In a case in which a molding restriction member for restricting a molding portion is formed on the base guide plate, when a molding process is completed, the molding restriction member may be removed by a selective etching process.

In the laser cutting process, a laser may be emitted to cut a connection tip formed on an end portion of the vertical contactor array.

The contactor block may further include first and second guide plates which are integrally formed with the vertical contactor arrays and distinguished according to a layout of a connecting element for coupling with each other, wherein one set of guide plates may be stacked to have a preset height by repeating a connection method in which the second guide plate is stacked on the first guide plate and another first guide plate is stacked on the second guide plate, and a molding layer may be formed by molding the plurality of vertical contactor arrays arranged in the first and second guide plates at the same time.

In a case in which a molding restriction member for restricting a molding portion is formed on the first and second guide plates, when a molding process is completed, the molding restriction member may be removed by a selective etching process.

Each of the first and second guide plates may include a flat plate shaped base plate and a connection plate, and connection elements formed in the base plate and the connection plate may include insertion protrusions and edge holes which are male-female couplable.

A cut groove, which passes through the connection plate to allow the vertical contactor arrays disposed above and below the connection plate to face each other, may be formed in the connection plate, and in a case in which the first and second guide plates are arranged by the connection elements, the plurality of vertical contactor arrays stacked in the first and second guide plates may be arranged based on a central axis.

In the base plate, the vertical contactor array may be integrally formed by a connection tip in a central portion and an edge hole is formed in an edge, an insertion protrusion may be formed to protrude from the connection plate, and the insertion protrusion formed to protrude from the connection plate of the first guide plate may be insertion-coupled to the edge hole formed in the base plate of the second guide plate.

The molding layer may be formed of an elastic material as an insulating material, and any one among polydimethylsiloxane (PDMS), polyurethane (PU), polyurethane acrylate (PUA), and silicon rubber may be used for the elastic material as the insulating material.

Another aspect of the present invention provides a method of manufacturing a contactor block of a self-aligning vertical probe card, the method including forming a seed layer on a substrate, forming probe holes disposed at predetermined intervals by applying a photoresist on the seed layer and removing the photoresist using a mask and an etching solution, forming a vertical contactor array by applying a nickel-copper alloy as a conductive material into the probe holes, performing a planarization process after the vertical contactor array is formed, forming a molding layer, which surrounds and supports the vertical contactor array using a molding restriction member, by removing the remaining photoresist through an additional photo process after the planarization process is performed, manufacturing individual base guide plates by removing the substrate and the seed layer, stacking the individual base guide plates to have a predetermined height, and forming a contactor block, which includes the vertical contactor array supported by the molding layer, by emitting a laser to the base guide plate to separate the base guide plate.

Still another aspect of the present invention provides a method of manufacturing a contactor block of a self-aligning vertical probe card, the method including manufacturing first and second guide plates, which include vertical contactor arrays and are distinguished according to a layout of a connection element for coupling with each other, using a micro-electro mechanical system (MEMS) process, assembling one set of guide plates, in which a plurality of vertical contactor arrays are arranged based on a central axis in a vertical direction and a horizontal direction, by alternately connecting and stacking first guide plates and second guide plates to have a predetermined height, forming a molding layer, which supports the plurality of arranged vertical contactor arrays, by injecting a molding member into the one set of guide plates and curing the molding member, and separating a contactor block, in which the plurality of vertical contactor arrays are buried in the molding layer, through a laser cutting process for separating the plurality of vertical contactor arrays from the one set of guide plates.

Each of the first and second guide plates may include a flat plate shaped base plate and a connection plate, connection elements formed on the base plate and the connection plate may include insertion protrusions and edge holes which are male-female couplable, a cut groove, which passes through the connection plate to allow the vertical contactor arrays disposed above and below the connection plate to face each other, may be formed in the connection plate, and in a case in which the first and second guide plates are arranged by the connection elements, the plurality of vertical contactor arrays formed in the one set of guide plates may be arranged based on the central axis.

The base plate of the second guide plate may be connected to the connection plate of the first guide plate, and the base plate of another first guide plate may be connected to the connection plate of the second guide plate.

In the base plate, the vertical contactor array may be integrally formed at a central portion and an edge hole is formed in an edge, an insertion protrusion may be formed to protrude upward from the connection plate, and the insertion protrusion formed to protrude from the connection plate of the first guide plate may be insertion-coupled to the edge hole formed in the base plate of the second guide plate.

The molding layer may be formed in a hexahedral shape in which the plurality of vertical contactor arrays are buried.

End portions of the vertical contactor arrays coupled to the first and second guide plates may be cut through a laser cutting process.

The molding layer may be formed of an elastic material as an insulating material, and any one among polydimethylsiloxane (PDMS), polyurethane (PU), polyurethane acrylate (PUA), and silicon rubber may be used for the elastic material as the insulating material.

### Advantageous Effects

According to the present invention, since an assembly of contactor blocks can be simply manufactured by stacking individual guide plates in layers using a mounting base and simply installed on a probe head module, work efficiency for assembling a probe card can be improved.

According to the present invention, since, after a plurality of types of the guide plates in which vertical contactors are integrally formed are stacked in an assembly method of alternately connecting the plurality of types of the guide plates, the contactor block formed through a molding process can be simply separated, and the separated contactor block can be easily and simply assembled to the probe card, a work time and manpower for assembly work can be significantly reduced when compared to a method of inserting vertical contactors into many insertion holes formed in guide plates like the related art.

According to the present invention, the contactor block having micro-pitches can be manufactured using a micro-electro mechanical system (MEMS) process and thus effectively respond to requirements for miniaturization of the probe card which tests a test target object.

### DESCRIPTION OF DRAWINGS

FIG. 1 is a schematic perspective view illustrating a probe head module of a probe card according to a related art.

FIG. 2 is a schematic cross-sectional view illustrating a needle unit of a probe card according to another related art.

FIG. 3 is a schematic perspective view illustrating a contactor block of a self-aligning vertical probe card according to a first embodiment of the present invention.

FIG. 4 is a schematic perspective view showing an operation in which individual base guide plates are stacked on a mounting base in order to form the contactor block of a self-aligning vertical probe card according to the first embodiment of the present invention.

FIG. 5 is a plan view illustrating the base guide plate of FIG. 4.

FIG. 6 is a cross-sectional view taken along line A-A of the base guide plate of FIG. 5.

FIG. 7 is a partially cut-away perspective view illustrating the base guide plate, on which a molding restriction member is formed, of FIG. 4.

FIG. 8 is a plan view illustrating the base guide plate of FIG. 7.

FIG. 9 is a plan view illustrating the base guide plate, on which a molding layer is formed, of FIG. 7.

FIG. 10 is a flowchart for describing a method of manufacturing the contactor block of a self-aligning vertical probe card according to the first embodiment of the present invention.

FIGS. 11 to 19 are views illustrating a manufacturing process of individual guide plates included in the contactor block of a self-aligning vertical probe card according to the first embodiment of the present invention.

FIGS. 20A-20B show perspective views for describing a structure of a first guide plate and a structure of a second guide plate which are included in a contactor block of a self-aligning vertical probe card according to a second embodiment of the present invention.

FIG. 21 is a perspective view illustrating the first guide plate and the second guide plate, on which a molding restriction member is formed and which are stacked and coupled one time, of FIG. 20.

FIG. 22 is a perspective view illustrating the first guide plate and the second guide plate, on which the molding restriction member is formed and which are stacked and coupled three times, of FIG. 20.

FIG. 23 is a perspective view illustrating a molding layer formed on the first and second guide plates of FIG. 22.

FIG. 24 is a perspective view showing a laser cutting process of separating the contactor block by emitting a laser beam to the first and second guide plates of FIG. 23.

FIG. 25 is a perspective view illustrating the contactor block separated through the laser cutting process of FIG. 24.

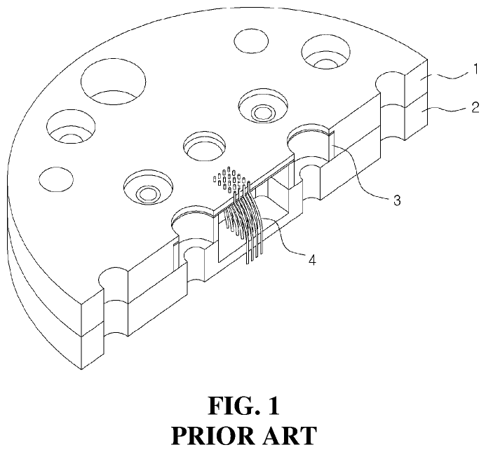

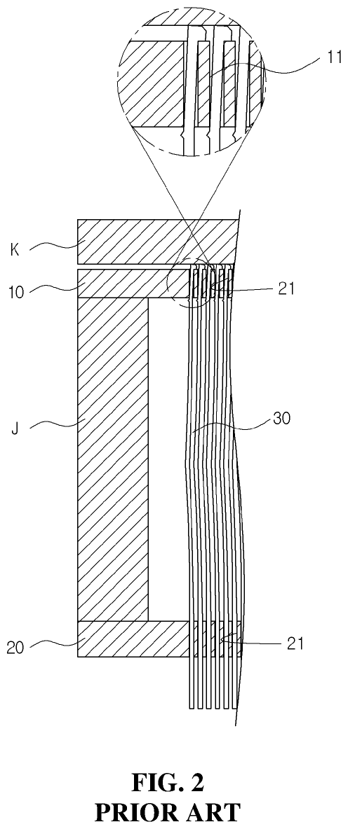

### MODES OF THE INVENTION

Hereinafter the present invention will be described by describing embodiments of the present invention with reference to the accompanying drawings. The same elements are denoted by the same reference numerals in the drawings. In addition, in the description of the invention, when it is determined that detailed descriptions of related well-known functions unnecessarily obscure the gist of the invention, the detailed descriptions thereof will be omitted. In addition, when a certain part “includes” a certain element, this does not exclude other components unless explicitly described otherwise, and other components may be further included.

### First Embodiment

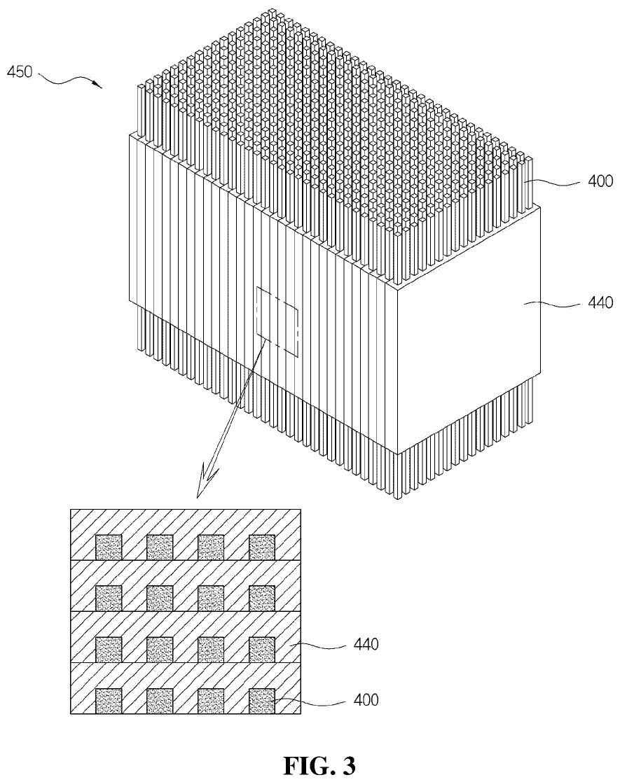

Referring to FIG. 3, a contactor block 450 of a self-aligning vertical probe card according to a first embodiment of the present invention includes a plurality of vertical contactor arrays 400 which are buried in molding layers 440 and of which portions of upper ends and lower ends are exposed. The vertical contactor arrays 400 include a plurality of vertical contactors which are disposed in a horizontal direction and formed to have the same length. The plurality of vertical contactor arrays 400 are arranged in one direction, and upper ends and lower ends of the vertical contactors are arranged at minute intervals in all directions.

Since the contactor block 450 has a structure that is installed on a probe head module, which is not illustrated, using a jig plate, an assembly operation of inserting the contactor block 450 into an insertion hole of an upper plate and a lower plate may be omitted, and thus work efficiency can be improved.

Although a state, in which a molding restriction member 401 is not formed on individual base guide plates 200, is illustrated in FIG. 4 for the sake of convenience of description, the molding restriction member 401 for restricting a portion to be molded is used on the individual base guide plates 200 manufactured using a micro-electro mechanical system (MEMS) process, which will be described below, according to FIGS. 11a to 11i. When a molding process is completed, the molding restriction member 401 is removed by selective etching, a molding layer 440 remains on the individual base guide plates 200, and then, the contactor block 450 is formed through a laser cutting process.

As illustrated in FIG. 4, the contactor block 450 may be formed by stacking the individual base guide plates 200 on a mounting base 100. That is, the individual base guide plates 200 manufactured using a MEMS process is fitted onto support rods 110 of the mounting base 100 and stacked in layers.

The plurality of support rods 110 having a predetermined height are formed to protrude from an edge of an upper surface of a flat body, which corresponds to a size and a shape of the base guide plate 200, of the mounting base 100.

The base guide plate 200 is formed in a rectangular shape, a plurality of insertion holes 210 vertically passing through the base guide plate 200 are formed in the peripheral corners thereof. As the plurality of insertion holes 210 are correspondingly fitted onto the plurality of support rods 110, the base guide plate 200 is stacked on the mounting base 100. That is, as a plurality of base guide plates 200 are stacked in layers from a lower portion to an upper portion above the mounting base 100, the plurality of base guide plates 200 may be arranged.

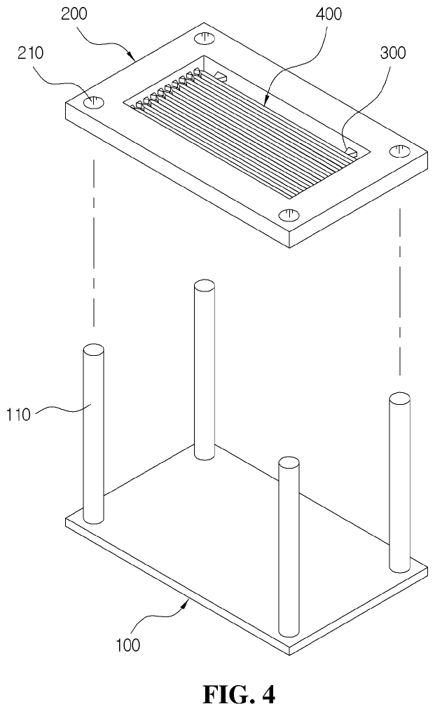

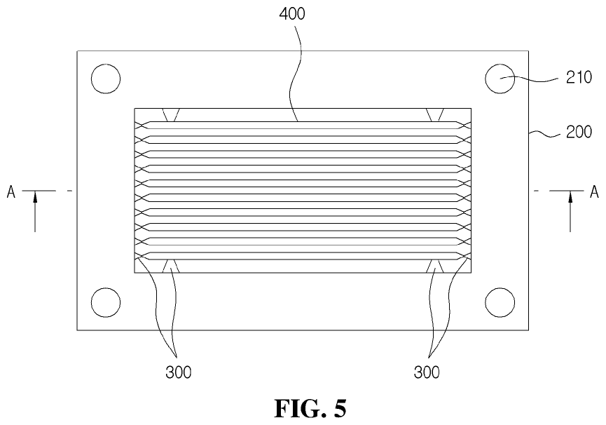

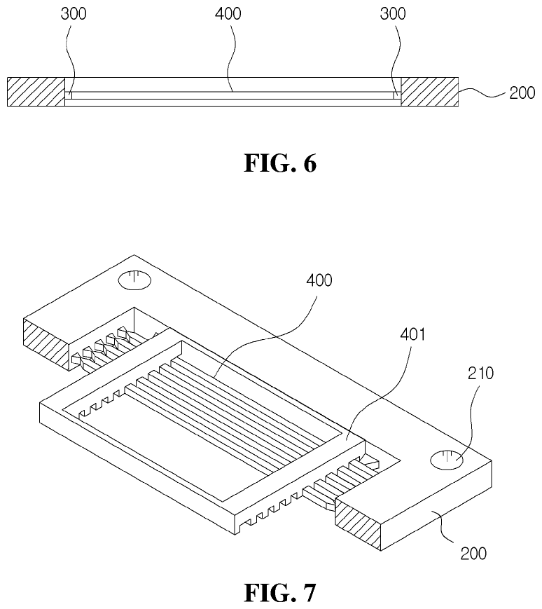

Referring to FIG. 5, the vertical contactor array 400 is formed in an inner groove formed in a central portion of the base guide plate 200, and the vertical contactor array 400 is connected by connection tips 300 formed on an inner edge of the base guide plate 200. In the connection tips 300, end portions of connection portions thinly protrude so as to be easily cut by laser cutting, and as illustrated in FIG. 6, empty spaces having a predetermined distance are formed above and below the vertical contactor array 400 extending in a longitudinal direction. The molding layer fills the empty spaces.

Since one end and the other end of the vertical contactor array 400 need to be exposed to come into contact with a space transformer and a test target object, the molding restriction member 401, which restricts the exposed portion from being molded is used. Referring to FIG. 7, an edge of the molding restriction member 401 is formed in a substantially quadrilateral shape, and a lower end portion is formed in a concave-convex shape to be fitted between the vertical contactors.

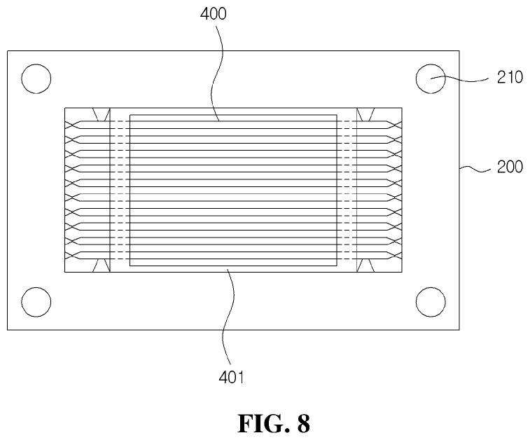

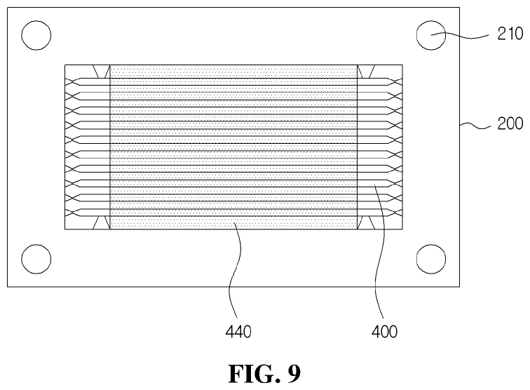

As illustrated in FIG. 8, a molding process of injecting a molding member into an empty space isolated by the molding restriction member 401 is performed. When a curing process of curing the molding member is performed, the molding layer 440 is formed in the central portion of the base guide plate 200. The molding layer 440 may surround and support a middle body excluding exposed portions of the upper end and the lower end of the vertical contactor array 400. Thereafter, when the molding restriction member 401 is removed by a selective etching process, as illustrated in FIG. 9, only the molding layer 440 remains on the base guide plate 200 from which the molding restriction member 401 is removed. The base guide plates 200 on each of which the molding layer 440 is formed may be stacked in layers using the mounting base 100.

As described with reference to FIG. 4, the insertion holes 210 of the base guide plate 200 are fitted onto the support rods 110 so that the base guide plates 200 are stacked in layers on the mounting base 100. After the plurality of base guide plates 200 are stacked as described above, when the connection tips 300 are cut through the laser cutting process, the base guide plates 200 may be separated, and as illustrated in FIG. 3, the contactor block 450 formed with the plurality of vertical contactor arrays 400 stacked in a vertical direction may be formed. In the contactor block 450, the plurality of vertical contactor arrays 400 are disposed at minute intervals in all directions.

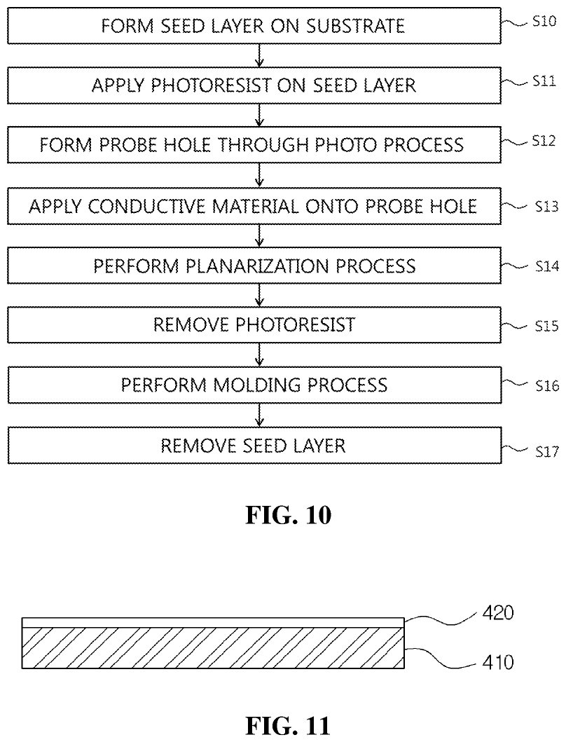

FIG. 10 is a flowchart for describing a method of manufacturing the contactor block of a self-aligning vertical probe card according to the first embodiment of the present invention, and FIGS. 11 to 19 are views illustrating a manufacturing process of individual guide plates included in the contactor block of a self-aligning vertical probe card according to the first embodiment of the present invention.

First, as illustrated in FIG. 11, a seed layer 420 is formed on a substrate 410 using sputtering, deposition, or the like. The seed layer 420 may be formed with a thickness of 1 to 2 μm (S10). In this case, the substrate 410 formed of an insulating material, such as ceramic, glass, and the like, may be used as the substrate 410, and copper, titanium, and chromium may be used as a material of the seed layer 420. Specifically, Ti/Cu or Cr/Cu may be used for the seed layer 420.

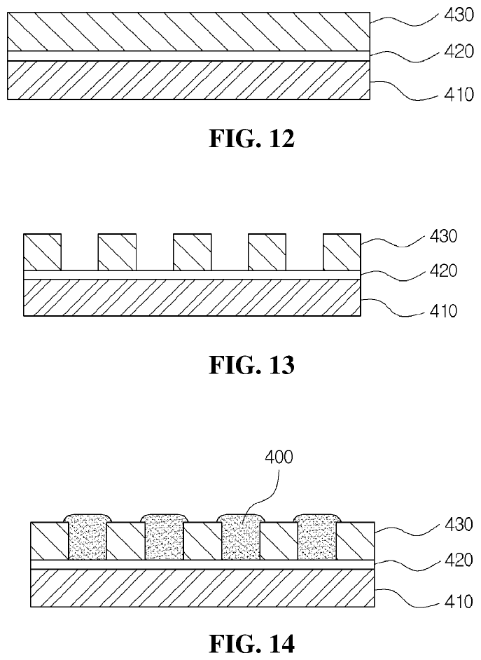

Then, as illustrated in FIG. 12, a photoresist 430 is applied on the seed layer 420 (S11). Then, as illustrated in FIG. 13, the photoresist 430 is removed by an etching solution using a mask to form probe holes at predetermined intervals (S12).

Then, as illustrated in FIG. 14, the probe holes are coated with a nickel-copper alloy as a conductive material to form the vertical contactor array 400 (S13).

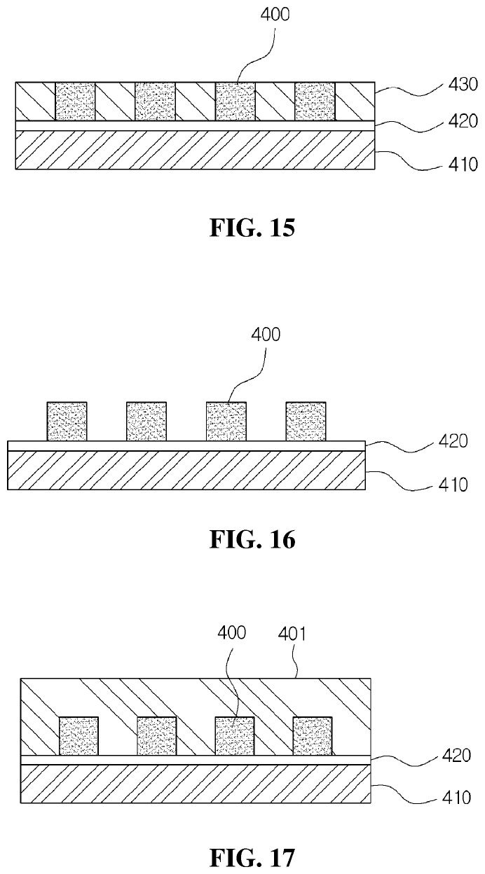

Then, as illustrated in FIG. 15, a planarization process is performed (S14).

Then, as illustrated in FIG. 16, the remaining photoresist is removed through an additional photo process (S15).

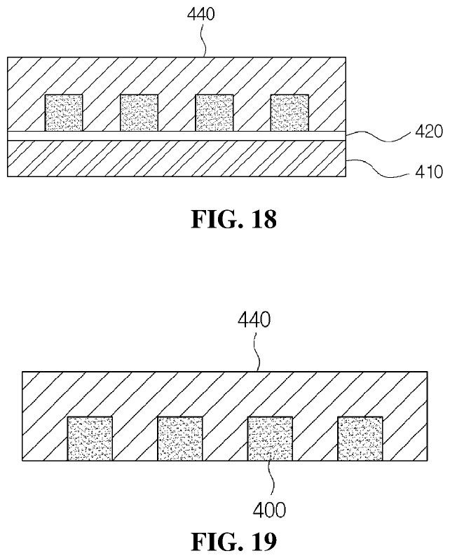

Then, as illustrated in FIG. 17, the molding restriction member 401 for restricting a molding portion is formed. Then, the molding member is injected between inner edges of the molding restriction member 401, and the molding member is cured. When a curing process of the molding member is completed, the molding restriction member 401 is removed through selective etching. As illustrated in FIG. 18, when the molding restriction member 401 is removed, the molding layer 440 for supporting the vertical contactor array 400 is formed. In this case, the molding layer 440 is formed of an elastic material as an insulating material, and for example, one of polydimethylsiloxane (PDMS), polyurethane (PU), polyurethane acrylate (PUA), various synthetic rubbers such as silicon rubber, and various resins may be used as the elastic material (S16). The vertical contactor array 400 buried in the molding layer 440 is disposed between and electrically connected to the space transformer and the test target object, and when a predetermined pressure is applied, the upper end and the lower end of the vertical contactor array 400 are pressed at the same time, a slight bending deformation in which a middle portion is bent temporarily occurs in the molding layer 440 formed of the elastic material, and when the contact pressure is removed, the vertical contactor array 400 is restored to the original form while the bent portion is straightened. Such temporary bending deformation may be repeated whenever the test target object is tested.

Then, as illustrated in FIG. 19, the base guide plate 200 in which the molding layer 440 and the vertical contactor array 400 are formed is completely formed by removing the substrate 410 and the seed layer 420 (S17). As described above, the contactor block 450 may be formed by stacking the individual base guide plates 200 in layers using the mounting base 100 of FIG. 4.

### Second Embodiment

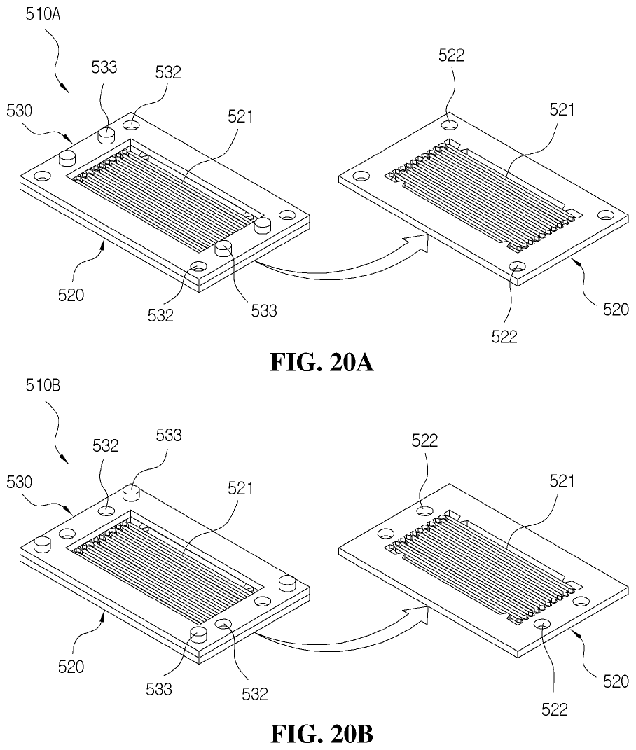

FIGS. 20A-20B show perspective views for describing a structure of a first guide plate and a structure of a second guide plate which are included in a contactor block of a self-aligning vertical probe card according to a second embodiment of the present invention.

A first guide plate 510A and a second guide plate 510B are manufactured by a MEMS process.

In this case, the MEMS process may form a seed layer on a substrate using sputtering, deposition, and the like. The seed layer may be formed with a thickness of 1 to 2 μm. In this case, the substrate formed of an insulating material, such as ceramic, glass, and the like, may be used as the substrate, and copper, titanium, and chromium may be used as a material of the seed layer. The MEMS process may include a process of forming a probe hole by applying a photoresist on an upper portion of the seed layer and removing the photoresist using an etching solution and a mask. In addition, the MEMS process has a concept including a process of applying a copper-nickel alloy as a conductive material on the probe hole to form a vertical contactor array, a planarization process, a process of removing the remaining photoresist, a process of forming a molding restriction member, a process of injecting and curing a molding member, a process of removing the molding restriction member through selective etching, and the like.

Each of the first and second guide plates 510A and 510B includes a base plate 520 and a connection plate 530 which are a pair. Each of the first and second guide plates 510A and 510B has a structure in which the connection plate 530 is disposed on the base plate 520. Each of the base plate 520 and the connection plate 530 includes connection elements for coupling the base plate 520 and the connection plate 530.

The first and second guide plates 510A and 510B include insertion protrusions and edge holes which are the connection elements which have different layouts but are functionally the same.

When the base plate 520 is manufactured through the MEMS process, a vertical contactor array 521 extending in a longitudinal direction in a bar shape is integrally formed at a central position of a flat plate shaped body, and the vertical contactor array 400 is connected to the base plate 520 by connection tips formed on an inner edge of the base plate 520.

A material of the vertical contactor array 521 may be the same as a material of the base plate 520. In the embodiment, a nickel-copper alloy may be used as a conductive material in the vertical contactor array 521.

When the connection plate 530 is manufactured through the MEMS process, insertion protrusions 533 are integrally formed around a cut groove 531 at a central position of a flat plate shaped body. In the embodiment, the cut groove 531 is formed in a quadrilateral shape, but any shape is acceptable as long as the vertical contactor array 521 can be exposed. The cut groove 531 is for allowing exposed vertical contactor arrays 521 positioned in an upper portion and a lower portion to face each other.

In the base plate 520 of the first guide plate 510A, a plurality of edge holes 522 are formed around the vertical contactor array 521, and the edge holes 522 are disposed at body corners. Unlike this, in the base plate 520 of the second guide plate 510B, a layout in which the vertical contactor array 521 is positioned at the central position is the same as that thereof, but a layout in which a plurality of edge holes 522 formed around the vertical contactor array 521 are formed along an edge is different therefrom.

In the connection plate 530 of the first guide plate 510A, a plurality of insertion protrusions 533 are formed to protrude to face each other along an edge around the cut groove 531, and a plurality of edge holes 532 are disposed to face each other at body corners. Unlike this, in the connection plate 530 of the second guide plate 510B, a layout in which the cut groove 531 is positioned at a central position of a flat plate shaped body is the same as that thereof, but a plurality of insertion protrusions 533 formed around the cut groove 531 are disposed at the body corners, and edge holes 532 are disposed along the edge.

In the first guide plate 510A, the edge holes 522 of the base plate 520 and the edge holes 532 of the connection plate 530 are disposed at corresponding positions in a vertical direction. As the insertion protrusions 533 of the connection plate 530 of the second guide plate 510B are inserted into the edge hole 522 and 523, which are vertically arranged as described above, of the first guide plate 510B, the first and second guide plates 510A and 510B are connected to each other.

The first guide plate 510A and the second guide plate 510B have the coupling structures in which the first guide plate 510A and the second guide plate 510B may be stacked in the vertical direction by the connection elements which are functionally the same but has only different layouts for coupling with each other.

In FIGS. 20A-20B, for the sake of convenience of description, a state in which molding restriction members 511 are not formed on the first and second guide plates 510A and 510B is illustrated, but actually, the molding restriction member 511 for restricting portions to be molded using the MEMS process are used in the first and second guide plates 510A and 510B. When the molding process is completed, the molding restriction member 511 is removed by selective etching, and a molding layer 540 remains, and after that, a contactor block 550 is formed through a laser cutting process, and this will be described in detail with reference to the accompanying drawings.

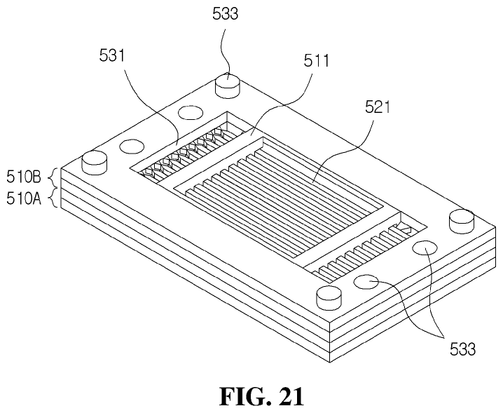

Referring to FIG. 21, in a state in which the first guide plate 510A is positioned at a lower end, the second guide plate 510B is stacked thereon. In this case, the molding restriction members 511 are formed on the first and second guide plates 510A and 510B.

When the base plate 520 of the second guide plate 510B is connected onto the connection plate 530 of the first guide plate 510A, the plurality of insertion protrusions 533 formed to protrude from the connection plate 530 of the first guide plate 510A pass through and are insertion-coupled to the plurality of edge holes 522 and 532 vertically arranged with the base plate 520 and the connection plate 530 of the second guide plate 510B. In this case, since the insertion protrusions 33 are exposed on the connection plate 530 of the second guide plate 510B positioned at an upper most portion, a new pair of the first guide plate 510A and the second guide plate 510B may be stacked and connected.

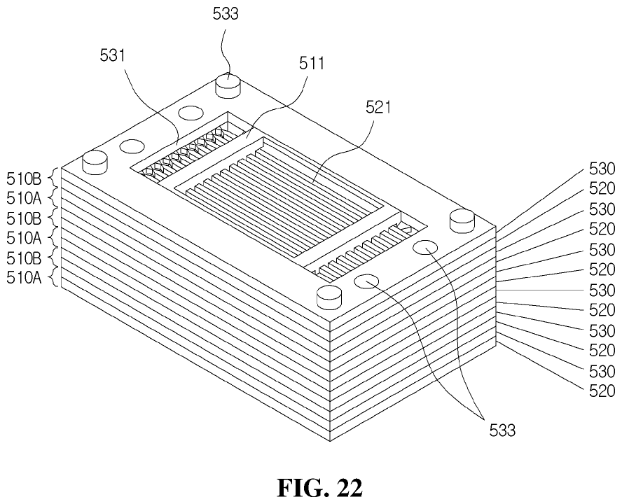

As illustrated in FIG. 22, a plurality of first and second guide plates 510A and 510B are additionally stacked to form a set of guide plates stacked to have a predetermined height. The first and second guide plates 510A and 510B stacked in the vertical direction are arranged along a central axis, the vertical contactor arrays 521 facing each other through the cut grooves 531 formed in each of the guide plates 510A and 510B are also arranged in vertical and horizontal directions.

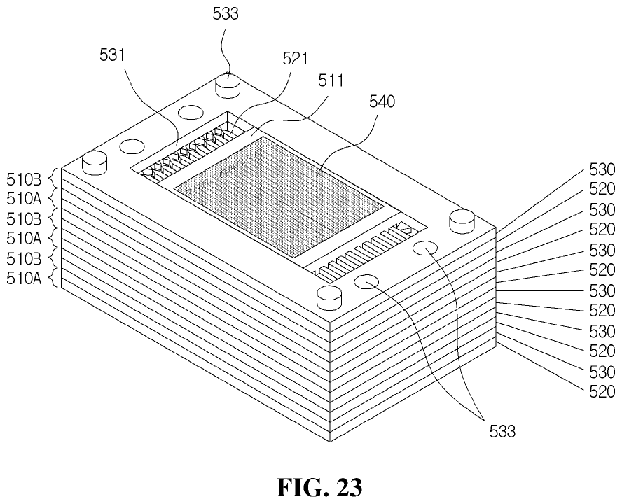

As illustrated in FIG. 23, while a liquid elastic material as a molding member is injected through the cut groove 531 exposed at the second guide plate 510B positioned at an upper most end and fills the cut grooves 531 passing therethrough in the vertical direction, the liquid elastic material surrounds the plurality of vertical contactor arrays 521 facing each other through the cut grooves 531. After that, when a curing process is performed thereon, a molding layer 540 for supporting the vertical contactor arrays 521 is formed.

The molding layer 540 is formed of an elastic material as an insulating material, and for example, one of PDMS, PU, PUA, various synthetic rubbers such as silicon rubber, and various resins may be used as the elastic material.

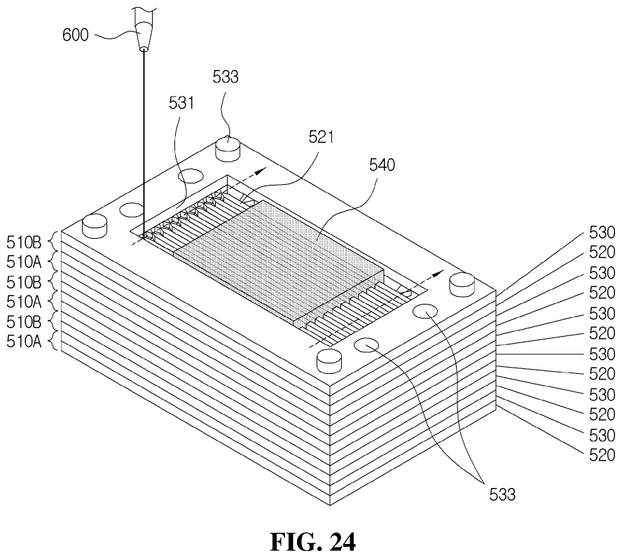

As illustrated in FIG. 24, a laser cutting process of emitting a laser in a dotted arrow direction to cut the connection tips is performed using a laser cutting apparatus 600. The vertical contactor arrays 521 stacked in a plurality of sets of the guide plates 510A and 510B may be separated using the laser cutting process.

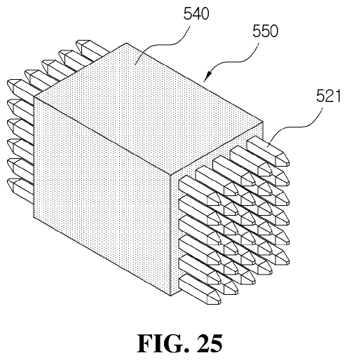

When the vertical contactor arrays 521 and end portions of the connection tips are cut in a laser cutting manner, as illustrated in FIG. 25, the plurality of guide plates 510A and 510B are separated and removed, and the contactor block 550 in which the plurality of vertical contactor arrays 521 are buried in the molding layer 540 is manufactured. The contactor block 550 is supported by the molding layer 540 and includes the plurality of vertical contactor arrays 521 which are arranged at micro-pitch intervals. Accordingly, the contactor block 550 may be easily and simply installed using a jig plate of a probe head module.

The number and a length of the vertical contactor arrays applied to the contactor block described in the embodiment may be changed according to a test environment of a test target object and the like, and a size of the contactor block may be adjusted in a manner of extending in all directions.

The above description is only exemplary, and it will be understood by those skilled in the art that the invention may be easily modified into other concrete forms without changing the technological scope and essential features.

### INDUSTRIAL USABILITY

The present invention can be applied to a test device called a probe card which applies an electrical signal to each chip and determines defects through a signal checked from the applied electrical signal. Particularly, the present invention can be suitable for a contactor block used in a probe head module of the probe card, can improve assembly work efficiency, and can reduce manufacturing costs.

1. A contactor block of a self-aligning vertical probe card, comprising:
one or more vertical contactor arrays which are manufactured through a micro-electro mechanical system (MEMS) process and in which a plurality of vertical contactors extending in a longitudinal direction are arranged parallel to a horizontal direction; and
a molding layer which exposes upper ends and lower ends of a plurality of vertical contactors included in the vertical contactor array and surrounds and supports the plurality of vertical contactors.

2. The contactor block of claim 1, further comprising base guide plates in which the vertical contactor array and the molding layer are integrally formed,
wherein the plurality of base guide plates are stacked in layers on a mounting base to form a contactor block, and
the contactor block is separated from the base guide plates using a laser cutting process.

3. The contactor block of claim 2, wherein:
a plurality of support rods having a predetermined height are formed to protrude from a flat plate shaped body of the mounting base; and
a plurality of insertion holes passing through the base guide plate are fitted onto the support rods of the mounting base so that the plurality of vertical contactor arrays are arranged.

4. The contactor block of claim 2, wherein, in a case in which a molding restriction member for restricting a molding portion is formed on the base guide plate, when a molding process is completed, the molding restriction member is removed by a selective etching process.

5. The contactor block of claim 2, wherein, in the laser cutting process, a laser is emitted to cut a connection tip formed on an end portion of the vertical contactor array.

6. The contactor block of claim 1, further comprising a first guide plate and a second guide plate which are integrally formed with the vertical contactor arrays and distinguished according to a layout of a connecting element for coupling with each other,
wherein one set of guide plates is stacked to have a preset height by repeating a connection method in which the second guide plate is stacked on the first guide plate and another first guide plate is stacked on the second guide plate, and
a molding layer is formed by molding the plurality of vertical contactor arrays arranged in the first and second guide plates at the same time.

7. The contactor block of claim 6, wherein, in a case in which a molding restriction member for restricting a molding portion is formed on the first and second guide plates, when a molding process is completed, the molding restriction member is removed by a selective etching process.

8. The contactor block of claim 6, wherein:
each of the first and second guide plates includes a flat plate shaped base plate and a connection plate; and
connection elements formed in the base plate and the connection plate include insertion protrusions and edge holes which are male-female couplable.

9. The contactor block of claim 8, wherein:
a cut groove, which passes through the connection plate to allow the vertical contactor arrays disposed above and below the connection plate to face each other, is formed in the connection plate; and
in a case in which the first and second guide plates are arranged by the connection elements, the plurality of vertical contactor arrays stacked in the first and second guide plates are arranged based on a central axis.

10. The contactor block of claim 8, wherein:
in the base plate, the vertical contactor array is integrally formed by a connection tip in a central portion and an edge hole is formed in an edge;
an insertion protrusion is formed to protrude from the connection plate; and
the insertion protrusion formed to protrude from the connection plate of the first guide plate is insertion-coupled to the edge hole formed in the base plate of the second guide plate.

11. The contactor block of claim 1, wherein:
the molding layer is formed of an elastic material as an insulating material; and
any one among polydimethylsiloxane (PDMS), polyurethane (PU), polyurethane acrylate (PUA), and silicon rubber is used for the elastic material as the insulating material.

12. A method of manufacturing a contactor block of a self-aligning vertical probe card, the method comprising:
forming a seed layer on a substrate;
forming probe holes disposed at predetermined intervals by applying a photoresist on the seed layer and removing the photoresist using a mask and an etching solution;
forming a vertical contactor array by applying a nickel-copper alloy as a conductive material into the probe holes;
performing a planarization process after the vertical contactor array is formed;
forming a molding layer, which surrounds and supports the vertical contactor array using a molding restriction member, by removing the remaining photoresist through an additional photo process after the planarization process is performed;
manufacturing individual base guide plates by removing the substrate and the seed layer;
stacking the individual basic guide plates to have a predetermined height; and
forming a contactor block, which includes the vertical contactor array supported by the molding layer, by emitting a laser to the base guide plate to separate the base guide plate.

13. A method of manufacturing a contactor block of a self-aligning vertical probe card, the method comprising:
manufacturing a first guide plate and a second guide plate, which include vertical contactor arrays and are distinguished according to a layout of a connection element for coupling with each other, using a micro-electro mechanical system (MEMS) process;
assembling one set of guide plates, in which a plurality of vertical contactor arrays are arranged based on a central axis in a vertical direction and a horizontal direction, by alternately connecting and stacking the first guide plate and the second guide plate to have a predetermined height;
forming a molding layer, which supports the plurality of arranged vertical contactor arrays, by injecting a molding member into the one set of guide plates and curing the molding member; and
separating a contactor block, in which the plurality of vertical contactor arrays are buried in the molding layer, through a laser cutting process for separating the plurality of vertical contactor arrays from the one set of guide plates.

14. The method of claim 13, wherein:
each of the first and second guide plates includes a flat plate shaped base plate and a connection plate;
connection elements formed on the base plate and the connection plate include insertion protrusions and edge holes which are male-female couplable;
a cut groove, which passes through the connection plate to allow the vertical contactor arrays disposed above and below the connection plate to face each other, is formed in the connection plate; and
in a case in which the first and second guide plates are arranged by the connection elements, the plurality of vertical contactor arrays formed in the one set of guide plates are arranged based on the central axis.

15. The method of claim 14, wherein the base plate of the second guide plate is connected to the connection plate of the first guide plate; and
the base plate of another first guide plate is connected to the connection plate of the second guide plate.

16. The method of claim 15, wherein:
in the base plate, the vertical contactor array is integrally formed at a central portion and an edge hole is formed in an edge;
an insertion protrusion is formed to protrude upward from the connection plate; and
the insertion protrusion formed to protrude from the connection plate of the first guide plate is insertion-coupled to the edge hole formed in the base plate of the second guide plate.

17. The method of claim 13, wherein the molding layer is formed in a hexahedral shape in which the plurality of vertical contactor arrays are buried.

18. The method of claim 13, wherein end portions of the vertical contactor arrays coupled to the first and second guide plates are cut through a laser cutting process.

19. The method of claim 13, wherein the molding layer is formed of an elastic material as an insulating material; and
any one among polydimethylsiloxane (PDMS), polyurethane (PU), polyurethane acrylate (PUA), and silicon rubber is used for the elastic material as the insulating material.
